(19) United States
(12) Patent Application Publication
(10) Pub. No.: US 2026/0130118 A1
(43) Pub. Date: May 7, 2026

(54) CURRENT-INDUCED SYNTHETIC ANTIFERROMAGNETIC SPIN-ORBIT TORQUE STRUCTURE WITH AN OXIDE SPACER

(71) Applicant: Powerchip Semiconductor Manufacturing Corporation, Hsinchu (TW)

(72) Inventors: Yuan-Chieh Tseng, Hsinchu (TW); Yu-Hsin Huang, Hsinchu (TW)

(73) Assignee: Powerchip Semiconductor Manufacturing Corporation, Hsinchu (TW)

(21) Appl. No.: 19/023,356

(22) Filed: Jan. 16, 2025

(30) Foreign Application Priority Data
Nov. 4, 2024 (TW) 113142100

(51) Int. Cl. H10N 50/10; G11C 11/16; H01F 10/32; H10N 50/85; H10N 52/80

(52) U.S. Cl. CPC H10N 50/10; H01F 10/3272; H10N 50/85; H10N 52/80; G11C 11/161

(57) ABSTRACT

A spin-orbit torque (SOT) magnetic device with synthetic antiferromagnetic (SAF) structure, including a SOT layer for providing a spin current, a SAF structure composed of a first ferromagnetic layer, a nickel oxide (NiO) exchange coupling layer and a second ferromagnetic layer, and a capping layer on the SAF structure. This magnetoelectric device of oxide SAF structure can achieve zero-field switching through current-induced SOT, and can be used as the free layer of a magnetoresistive random access memory (MRAM).

### BACKGROUND OF THE INVENTION

### 1. Field of the Invention

The present invention relates generally to a spin orbit torque (SOT) magnetic device, and more specifically, to a SOT magnetic device having a synthetic antiferromagnetic structure.

### 2. Description of the Prior Art

The synthetic antiferromagnetic (SAF) structure consists of two magnetic layers separated by a non-magnetic spacer layer, which plays a pivotal role in regulating the interaction between the two magnetic layers through interlayer exchange coupling (IEC). This effect allows the non-magnetic spacer to control the magnetic moments of the two adjacent magnetic layers, enabling either ferromagnetic coupling (where the magnetic moments are aligned in the same direction) or antiferromagnetic coupling (where the magnetic moments are aligned in opposite directions). This is particularly significant for SAF structures exhibiting perpendicular magnetic anisotropy (PMA), which offer great potential for application in magnetic storage devices, magnetic sensors and spintronic device, such as spin valves or magnetic tunnel junctions (MTJs). These devices are valued for their high magnetic stability, integration, and reliability in switching.

In conventional designs, the middle non-magnetic spacer is typically made from non-magnetic metal like ruthenium (Ru), osmium (Os), rhenium (Re), chromium (Cr), rhodium (Rh), copper (Cu), niobium (Nb), molybdenum (Mo), tungsten (W), iridium (Ir), vanadium (V). However, these metals are highly conductive, which can result in the input write current being easily shunted into the metal spacer layer, diminishing the current available for the spin-orbit torque (SOT) layer responsible for generating the necessary spin current. Consequently, a higher spin current density is required to flip the magnetic moment of the free layer within the SAF structure to achieve the desired storage functionality. Furthermore, SAF structures with metal spacers face thermal stability problems and may struggle to maintain stable and consistent IEC performance at elevated temperatures. Therefore, there is a pressing need for those of skilled in the art to refine existing SAF structures in order to realize spintronic devices that feature ultra-low power consumption and enhanced performance.

### SUMMARY OF THE INVENTION

In light of the aforementioned limitations of the prior art, the present invention introduces a novel synthetic antiferromagnetic (SAF) structure, along with a spin orbit torque (SOT) magnetic device based on this structure, which is characterized by utilizing nickel oxide (NiO) as the spacer material in the SAF configuration, a choice that enables field-free switching, offering a significant improvement over traditional designs.

The objective of the present invention is to provide a spin-orbit torque magnetic device having a synthetic antiferromagnetic structure, including: a spin-orbit torque layer, with both ends respectively connected to a first lower electrode and a second lower electrode to provide a spin current flowing through the spin-orbit torque layer; a synthetic antiferromagnetic structure, formed by stacking a first ferromagnetic layer, a nickel oxide exchange coupling layer and a second ferromagnetic layer, wherein both sides of the first ferromagnetic layer are respectively and directly connected with the spin-orbit torque layer and the nickel oxide exchange coupling layer, and both sides of the nickel oxide exchange coupling layer are respectively and directly connected with the first ferromagnetic layer and the second ferromagnetic layer, and both sides of the second ferromagnetic layer are respectively and directly connected with the nickel oxide exchange coupling layer and a capping layer; and the capping layer, in direct contact with said second ferromagnetic layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic cross-sectional view of a spin-orbit torque (SOT) device with synthetic antiferromagnetic (SAF) structure in accordance with an embodiment of the present invention;

FIG. 2 presents a switching graph of a current-induced magnetic moment in a SAF layer structure, specifically for the W(3 nm)/Pt(5 nm)/Co(1 nm)/NiO(1.5 nm)/Co(1 nm)/Pt(1 nm) configuration;

FIG. 3 shows a graph depicting the relationship between the thickness of the nickel oxide (NiO) exchange coupling layer and the magnetic field offset intensity resulting from the coupling, in accordance with an embodiment of the present invention;

FIG. 4 displays the hysteresis curve of a SAF structure from prior art;

FIG. 5 illustrates the hysteresis curve of a SAF structure in accordance with an embodiment of the present invention; and

FIG. 6 illustrates the hysteresis curve of a SAF structure under both vertical and horizontal applied fields, in accordance with an embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

First, please refer to FIG. 1, which presents a schematic cross-sectional view of a spin-orbit torque (SOT) magnetic device incorporating a synthetic antiferromagnetic (SAF) structure, in accordance with an embodiment of the present invention. As depicted in the figure, the SOT magnetic device 10 of the present invention includes a SOT layer 100, a SAF structure 110, a capping layer 112 and other components. Notably, the SOT structure 110 and the capping layer 112 are arranged in a stacked configuration atop the SOT layer 100. In this embodiment, the SOT layer 100 extends across the entire planar area of the stacked structure, ensuring that the spin current can flow through the full planar area. In the embodiment of the present invention, the SAF structure 110 is formed by a first ferromagnetic layer 104, a nickel oxide (NiO) exchange coupling layer 106, and a second ferromagnetic layer 108, wherein the first ferromagnetic layer 104 is in direct contact with the SOT layer 100, while the NiO exchange coupling layer 106 is sandwiched between the first ferromagnetic layer 104 and the second ferromagnetic layer 108, making direct contact with both ferromagnetic layers. The other side of the second ferromagnetic layer 108 is in direct contact with the capping layer 112.

Referring once again to FIG. 1, in the embodiment of the present invention, the SOT layer 100 serves the primary function of providing spin current. The material of the SOT layer 100 is selected for its high spin-charge conversion (SCC) efficiency. Preferred materials for this purpose include tungsten (W) or tantalum (Ta). In the present example, a W/Pt multilayer structure is employed. When a plane current (current-in-plane) passes through the SOT layer 100, a spin current is generated in a direction vertical to the plane due to the Spin Hall effect. Consequently, as the spin current flows through the ferromagnetic layer 104 in the SOT structure 110, the magnetic moment of the ferromagnetic layer is switched to a specific direction. This effect enables applications such as data storage or magnetic field sensing.

Refer once again to FIG. 1, the SOT layer 100 and the capping layer 112 are positioned on either side of the two ferromagnetic layers 104 and 108 within the SOT structure 110. In certain embodiments, the SOT layer 100 and the capping layer 112 can be considered as part of the ferromagnetic structure of the SOT structure 110, though not limited thereto. For instance, the materials of both the first ferromagnetic layer 104 and the second ferromagnetic layer 108 may include one or more elements from the group consisting of nickel (Ni), iron (Fe), cobalt (Co), manganese (Mn) or the compounds thereof, with thickness ranging from 5 to 150 Å. The SOT layer 100 and the capping layer 112 may be composed of platinum (Pt), so that the first ferromagnetic layer 104 and the SOT layer 100 constitute a Co/Pt multilayer structure, and the second ferromagnetic layer 108 and the capping layer 112 constitute a Co/Pt multilayer structure. These materials are symmetrically positioned on either side of the NiO exchange coupling layer 106, which acts as a spacer. This layered configuration can be regarded as a free layer in a magnetic tunnel junction (MTJ) with perpendicular magnetic anisotropy (PMA).

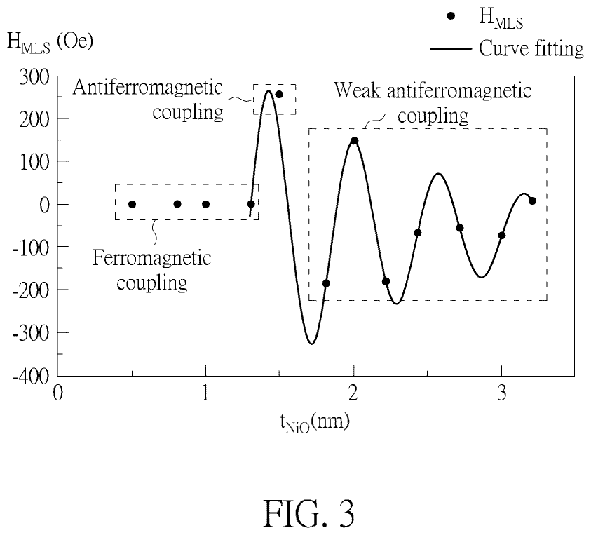

In the embodiment of the present invention, unlike the use of metal in conventional skill, the exchange coupling layer 106, serving as the spacer in the SAF structure, is composed of nickel oxide (NiO). This material exhibits a pronounced interlayer exchange coupling (IEC) effect and demonstrates characteristics consistent with the RKKY (Ruderman-Kittel-Kasuya-Yosida) oscillation. The thickness of the NiO exchange coupling layer 106 can range from 3 to 30 Å. As shown in FIG. 3, the graph illustrates the magnetic field offset intensity H_{MLS} resulting from the coupling, which varies with the thickness t_{NiO} of the NiO exchange coupling layer 106 in accordance with the present invention. From the figure, it is evident that the NiO exchange coupling layer 106 in the SAF structure exhibits RKKY oscillation with significant perpendicular magnetic anisotropy (PMA) when the thickness is below 3 nm. As the thickness of the NiO exchange coupling layer 106 decreases, the amplitude of the magnetic field oscillation becomes progressively larger, reaching a maximum IEC energy (approximately 0.017 erg/cm²) when the thickness is 1.5 nm, indicative of antiferromagnetic coupling. The IEC can be quantified by multiplying the magnetic field offset strength H_{MLS} caused by the coupling by the saturation magnetization, and further multiplying by the thickness of the individual ferromagnetic layers. This antiferromagnetic coupling enables the free layer (e.g., the second ferromagnetic layer 108) in the SAF structure to switch the alignment direction of its magnetic moment, making it suitable for use as an MTJ component in an SOT device. When the thickness exceeds 1.5 nm, the coupling weakens, resulting in a generalized SAF structure, but still retaining the ability to switch the alignment direction of magnetic moment. In contrast, when the thickness is below 1.5 nm, ferromagnetic coupling is observed. As depicted in the figure, as the thickness of the NiO exchange coupling layer 106 decreases, the amplitude of its magnetic field oscillation increases, meaning that the thickness t_{NiO} can be effectively utilized to control the coupling strength of the NiO exchange coupling layer 106 in practical application. Furthermore, since NiO is an oxide with low conductivity, the spin current in the SOT layer is not be diluted by shunting, which is a significant advantage, as it allows for lower SOT switching current densities. Additionally, NiO boasts an exceptionally high Néel temperature (approximately 520 K), ensuring stable and consistent exchange coupling even in high-frequency and high-temperature operating environments, further enhancing its suitability for such applications.

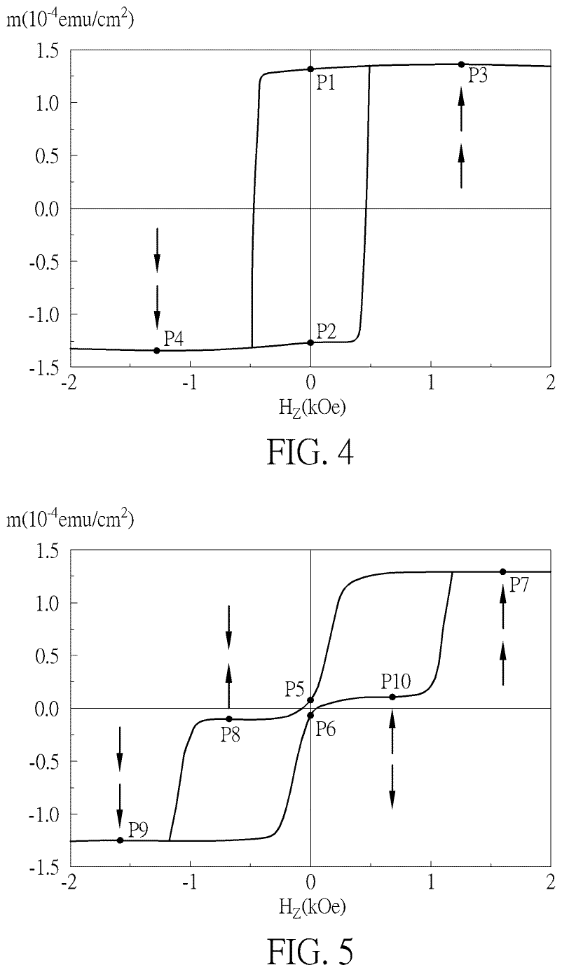

On the other hand, please refer to FIG. 4, which presents a hysteresis curve graph of a ferromagnetic coupling device from prior art. For traditional ferromagnetic coupling magnetic devices, the hysteresis curve is depicted in FIG. 5. In a positive magnetic field environment (e.g., H_{z}>0.5 kOe), the magnetic moments of the two ferromagnetic layers in the SAF structure are oriented upward. Conversely, in a negative magnetic field environment (e.g., when H_{z}<−0.5 kOe), the magnetic moments of the two ferromagnetic layers in the SAF structure are oriented downward. As shown in the figure, in the absence of an external magnetic field (i.e., when H_{z} is near 0, as indicated by points P1 and P2), the two ferromagnetic layers exhibit substantial positive and negative remanence, and the coercive force should be overcome to switch the magnetic moments. Consequently, SOT devices that utilize metal spacers generally require the application of a sufficiently strong magnetic field (e.g., H_{z}=±0.5 kOe) or the provision of high-density spin currents to achieve magnetic moment switching.

In contrast, please refer to FIG. 5, which shows a hysteresis curve graph of the SAF structure 110 according to an embodiment of the present invention. As depicted in the figure, the positive and negative remanence of the SAF structure 110 is nearly zero in a zero magnetic field environment (as indicated by points P5 and P6). This behavior demonstrates a significant reduction in the energy barrier that needs to be overcome for switching the positive and negative magnetic moments. As a result, the zero-field switching can be achieved with only a very small switching current density, representing a key advantage of the present invention.

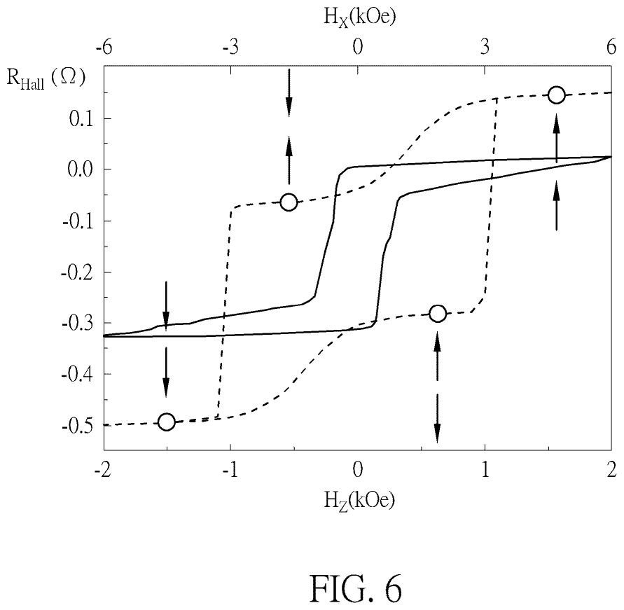

Furthermore, it can also be observed from the figure that the switching behavior of the SAF structure 110 in the present invention differs significantly from that of the conventional skill shown in FIG. 4. In the conventional skill, as illustrated in FIG. 4, when the magnetic field changes from a positive magnetic field to a negative magnetic field, the magnetic moments of the two ferromagnetic layers will simultaneously flip downward (P3→P1→P4) once the negative magnetic field reaches a certain intensity. Conversely, when the magnetic field changes from a negative magnetic field to a positive magnetic field, the magnetic moments of both ferromagnetic layers flip upward at the same time (P4→P2→P3) once the positive magnetic field reaches a certain intensity. In contrast, in the present invention, as depicted in FIG. 5, when the magnetic field changes from a positive magnetic field to a negative magnetic field, the magnetic moment of the second ferromagnetic layer 108 in the two ferromagnetic layers initially flips downward (at point P8). Only when the negative magnetic field exceeds a certain intensity threshold does the magnetic moment of the first ferromagnetic layer 104 flips downward as well (at point P9). Similarly, when the magnetic field changes from a negative magnetic field to a positive magnetic field, the magnetic moment of the second ferromagnetic layer 108 in the two ferromagnetic layers first flips upward (at point P10), and once the positive magnetic field exceeds a certain intensity threshold does the magnetic moment of the first ferromagnetic layer 104 also flip upward (at point P7). FIG. 6 presents the hysteresis curve graph of a W(3 nm)/Pt(5 nm)/Co(1 nm)/NiO(1.5 nm)/Co(1 nm)/Pt(1 nm) SAF layer structure under an applied vertical and horizontal field. The dotted line represents the hysteresis curve under the vertical field, while the solid line corresponds to the hysteresis curve under the horizontal field. Under the application of a horizontal field, the Hall resistance R_{Hall} ranges from 0 to −0.33, which lies between the anti-parallel states observed under the vertical field. Since the horizontal field is applied during current-induced switching, this structure alternates between two antiparallel states when current-induced switching occurs, rather than flipping only a single ferromagnetism layer or switching between two parallel states. This highlights the distinct switching behavior of the SAF structure 110 in the present invention compared to that of conventional skills.

In the aspect of fabrication, all metal layers in the SOT magnetic device 10 can be deposited by DC sputtering, including the SOT layer 100, the first ferromagnetic layer 104, the second ferromagnetic layer 108 and the capping layer 112. The NiO exchange coupling layer 106 can be deposited by radio frequency (RF) sputtering using an insulating NiO target. Specifically, the SOT layer 100 may be composed of a tungsten (W)/platinum (Pt) multilayer structure, with a tungsten thickness of approximately 3 nm and a platinum thickness of approximately 5 nm. The first ferromagnetic layer 104 and the second ferromagnetic layer 108 can be made of cobalt (Co), each with a thickness of about 1 nm. The thickness of NiO exchange coupling layer 106 is preferably less than 3 nm. The capping layer 112 is typically made of platinum, with a thickness of approximately 1 nm.

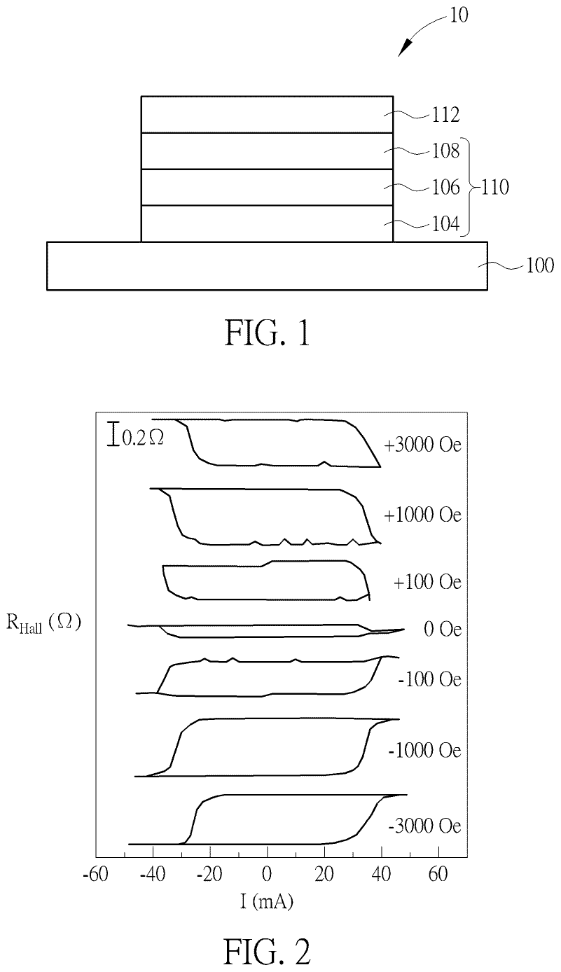

The Keithley6221 is used as the current source to deliver a pulse current. A small current (1 mA) is applied after the pulse is completed, and the Keithley2000 is employed to measure abnormal Hall voltage (V_{xy}). For each measurement, an external magnetic field (Hₓ) is applied along the x direction (the system operates under zero-field switching if no external field is applied). The current is applied in the x direction, starting from a small positive value, increasing to a large positive current, then decreasing to a large negative current, and finally returning to a large positive current, thus completing a full loop, as illustrated in FIG. 2. The abnormal Hall resistance (R_{xy}) is obtained by dividing the measured abnormal Hall voltage (V_{xy}) by the applied current. The Hall resistance (R_{xy}) is used to reflect the state of the magnetic moment, with the abnormal Hall resistance defining the direction of magnetic moment.

The current flows into the heavy metal layer (e.g. W/Pt) from the bottom, generating a spin current (SOT) that induces a magnetic moment flip in the Co ferromagnetic layers with perpendicular anisotropy, which is positioned above and below the NiO layer. As shown in FIG. 5, during the flipping process, although the magnetic moments of the upper and lower Co layers flip in opposite directions (at points P8 and P10), they continue to maintain an antiparallel alignment.

FIG. 2 illustrates the current-induced magnetic moment switching in the W(3 nm)/Pt(5 nm)/Co(1 nm)/NiO(1.5 nm)/Co(1 nm)/Pt(1 nm) SAF layer structure. As shown in the figure, the Hall resistance difference is approximately 0.4 Ω when the magnetic moment is fully flipped (+3000 Oe), and zero-field switching results in a 10-15% complete switching. The degree of zero-field switching is quantified by the zero-field switching resistance difference divided by a complete switching resistance difference. The switching current density is calculated by dividing the switching current by the area of Hall bar, which yields a value of approximately 4.2×10⁷ A/cm².

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A spin-orbit torque magnetic device having a synthetic antiferromagnetic structure, comprising:
a spin-orbit torque layer, with both ends respectively connected to a first lower electrode and a second lower electrode to provide a spin current flowing through said spin-orbit torque layer;
a synthetic antiferromagnetic structure, formed by stacking a first ferromagnetic layer, a nickel oxide exchange coupling layer and a second ferromagnetic layer, wherein both sides of said first ferromagnetic layer are respectively and directly connected with said spin-orbit torque layer and said nickel oxide exchange coupling layer, and both sides of said nickel oxide exchange coupling layer are respectively and directly connected with said first ferromagnetic layer and said second ferromagnetic layer, and both sides of said second ferromagnetic layer are respectively and directly connected with said nickel oxide exchange coupling layer and a capping layer; and
said capping layer, in direct contact with said second ferromagnetic layer.

2. The spin-orbit torque magnetic device having a synthetic antiferromagnetic structure of claim 1, wherein a material of said spin-orbit torque layer is heavy metal, comprising tungsten (W) or tantalum (Ta).

3. The spin-orbit torque magnetic device having a synthetic antiferromagnetic structure of claim 1, wherein each of said first ferromagnetic layer and said second ferromagnetic layer at least comprises one or more elements from the group of nickel (Ni), iron (Fe), cobalt (Co), manganese (Mn) or the compounds thereof, with a thickness ranging from 5 to 150 Å.

4. The spin-orbit torque magnetic device having a synthetic antiferromagnetic structure of claim 1, wherein a thickness of said nickel oxide exchange coupling layer ranges from 3 to 30 Å.

5. The spin-orbit torque magnetic device having a synthetic antiferromagnetic structure of claim 1, further comprising an upper electrode in direct contact with said capping layer to provide a reading current.

6. The spin-orbit torque magnetic device having a synthetic antiferromagnetic structure of claim 1, wherein a hysteresis curve of said artificial antiferromagnetic structure has a positive remanence and a negative remanence close to zero when an applied magnetic field is zero.
